(19) United States
(12) Patent Application Publication
(10) Pub. No.: US 2007/0042131 A1
(43) Pub. Date: Feb. 22, 2007

(54) Non-intrusive plasma monitoring system for arc detection and prevention for blanket CVD films

(75) Inventors: Jyr Hong Soo, Santa Clara, CA (US); Vu Ngoc Tran Nguyen, Santa Clara, CA (US); Steven Reiter, Santa Clara, CA (US); Jason Foster, San Jose, CA (US); Bok Hoen Kim, San Jose, CA (US); Hichem M'Saad, Santa Clara, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., A Delaware corporation, Santa Clara, CA (US)

(21) Appl. No.: 11/208,835

(22) Filed: Aug. 22, 2005

(51) Int. Cl. H05H 1/24; B05C 11/00; C23C 16/00

(52) U.S. Cl. 427/569; 118/712; 118/723 R

(57) ABSTRACT

Methods and systems of diagnosing an arcing problem in a semiconductor wafer processing chamber are described. The methods may include coupling a voltage probe to a process-gas distribution faceplate in the processing chamber, and activating an RF power source to generate a plasma between the faceplate and a substrate wafer. The methods may also include measuring the DC bias voltage of the faceplate as a function of time during the activation of the RF power source, where a spike in the measured voltage at the faceplate indicates an arcing event has occurred in the processing chamber. Methods and systems to reduce arcing in a semiconductor wafer processing chamber are also described.

### CROSS-REFERENCES TO RELATED APPLICATIONS

NOT APPLICABLE

### BACKGROUND OF THE INVENTION

The fabrication of modern semiconductor devices commonly involve the formation of thin films on a semiconductor wafer substrate though the chemical reaction of gases. Such deposition processes are referred to a chemical vapor deposition (CVD). Conventional thermal CVD processes supply reactive gases to the substrate surface where heat-induced chemical reactions take place to produce a desired film.

An alternative method of depositing layers over a substrate includes plasma enhanced CVD (PECVD) techniques. Plasma enhanced CVD techniques promote excitation and/or dissociation of the reactant gases by the application of radio frequency (RF) energy to a reaction zone near the substrate surface, thereby creating a plasma. The high reactivity of the ionized species in the plasma reduces the energy required for a chemical reaction to take place, and thus lowers the temperature for such CVD processes as compared to thermal CVD processes. The relatively low temperature of some PECVD processes helps semiconductor manufacturers lower the overall thermal budget in the fabrication of some integrated circuits.

Semiconductor device geometries have dramatically decreased in size since they were first introduced decades ago. Such decreases in size have in part been made possible by advances in semiconductor manufacturing equipment, such as the substrate processing chambers used for PECVD processing. Some of the technology advances include advances that are reflected in the design and manufacture of certain CVD deposition systems in use in fabrication facilities today, while others are in various stages of development and will soon be in widespread use throughout the fabrication facilities tomorrow.

One technology advance commonly used in today's fabrication facilities includes the use of a PECVD technique often referred to as mixed frequency PECVD in which both high and low frequency RF power are employed to generate plasma and to promote ion bombardment of a substrate. One such mixed frequency method couples both high and low frequency RF power to a metal gas distribution manifold that may also act as an electrode for directing the RF power into the processing chamber. The high-frequency RF power is the primary mechanism that dissociates the plasma precursor materials while application of the low-frequency RF power promotes ion bombardment of a substrate positioned on a grounded substrate support, which may also function as a second electrode. In additional embodiments of mixed frequency methods, the high-frequency RF power may be coupled to a gas distribution manifold and the low-frequency RF power may be coupled to a substrate holder. Another technology advance used in some currently available PECVD deposition chambers includes the use of conical holes in the gas distribution manifold to increase the dissociation of gases introduced into the chamber.

Advances in technologies such as the ones described above are not without restrictions. For example, while mixed frequency PECVD technique have proved beneficial in a variety of applications, the simultaneous application of the high and low-frequency RF waveforms should be controlled to avoid interferences that can result in high voltages and arcing at the gas distribution manifold. This arcing may be evidenced by a glow within the hold of the gas distribution manifold, and by a reduction in the deposition rate as the amplitude of the high-frequency voltage is increased. Arcing in PECVD processes may also occur between the gas distribution faceplate and the substrate wafer when there are instabilities in the plasma in the processing chamber. This arcing can cause defects in the substrate wafer surface that reduces the yield of working semiconductor devices fabricated on the wafer.

Current methods of diagnosing arcing probems in PECVD processing chambers have significant limitations. One method involves inserting a voltage probe (typically referred to as an S-probe) into the chamber plasma to measure voltage changes that indicate plasma instability and arcing. Unfortunately, the S-probe itself can interfere with and destabilize the plasma it is trying to measure. Contamination and corrosion of the surface of the S-probe can also create a source of particulates which can contaminate the underlying substrate wafer. Another method involves taking VRMS measurements of the RF power source (or sources), which supply RF power to generate a plasma in the processing chamber. While this method avoids placing a probe directly in the plasma, the measurements generally suffer from poor signal-to-noise ratios and poor time resolution that can make it difficult to detect evidence of arcing (e.g., voltage spikes). Thus, there remains a need for methods and systems to diagnose arcing in plasma processing chambers which are non-invasive and provide more reliable detection of arcing.

### BRIEF SUMMARY OF THE INVENTION

Embodiments of the invention relate to methods of diagnosing an arcing problem in a semiconductor wafer processing chamber. The methods may include coupling a voltage probe to a process-gas distribution faceplate in the processing chamber, and activating an RF power source to generate a plasma between the faceplate and a substrate wafer. The methods may also include measuring the DC bias voltage of the faceplate as a function of time during the activation of the RF power source, where a spike in the measured voltage at the faceplate indicates an arcing event has occurred in the processing chamber.

Embodiments of the invention also relate to systems to diagnose an arcing problem in a semiconductor wafer processing chamber. The systems may include a voltage probe coupled to a process-gas distribution faceplate in the processing chamber, and a voltage measurement device to measure the DC bias voltage of the faceplate as a function of time. The systems may also include a display coupled to the voltage measurement device to display a plot of faceplate voltage measurements as a plasma is generated in the processing chamber, where a spike in the plot indicates an arcing event has occurred in the processing chamber.

Embodiments of the invention may further relate to methods to reduce arcing in a semiconductor wafer processing chamber. The methods may include the step of measuring a spike in a DC bias voltage of a process-gas distribution faceplate as a plasma is formed in the processing chamber, where the spike indicates there is arcing in the chamber. The methods may also include adjusting a flow rate of a plasma precursor material supplied to the chamber, and adjusting a ramp rate for RF power supplied to the chamber to form the plasma from the plasma precursor material.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

FIG. 1 is a flowchart illustrating a method to detect arcing in a semiconductor wafer processing chamber according to embodiments of the invention;

FIG. 2 is a flowchart illustrating a method of reducing arcing in a semiconductor wafer processing chamber according to embodiments of the invention;

FIGS. 3A-B show cross-sectional views of a plasma enhanced chemical vapor deposition system according to embodiments of the invention;

FIGS. 3C-D show exploded views of parts of the PECVD chamber shown in FIG. 1A;

FIG. 3E shows a simplified diagram of a system monitor and CVD system in a multichamber system, according to embodiments of the invention;

FIGS. 4A-B show experimental plots of faceplate voltage over time during the plasma deposition of an FSG layer;

FIGS. 5A-B show experimental plots of faceplate voltage over time for different low-frequency RF power levels; and

FIG. 6 shows an experimental plot of faceplate voltage over time during the plasma deposition of an integrated USG/FSG layer.

### DETAILED DESCRIPTION OF THE INVENTION

The present invention relates to methods and systems for diagnosing arcing problems in semiconductor wafer processing chambers. The methods and systems include voltage measurements of a process-gas distribution faceplate that may also act as an electrode for directing RF power into a processing chamber to generate a plasma. Voltage measurements may be taken with a voltage probe coupled to the faceplate that does not make direct contact with the plasma. The voltage probe may also be coupled to a voltage measurement device that measures the DC bias voltage of the faceplate as a function of time. The probe and measurement device may have fast response times capable of sampling the faceplate voltage at a rate of about 100,000 times/second (i.e., 100 kHz) or more.

The present methods and systems may also include generating a plot of the faceplate voltage over time and identifying features in the plot that indicate arcing has occurred in the plasma chamber. These features may include, for example, an abrupt change in voltage (e.g., a voltage spike). The character and timing of the voltage spike during the course of a plasma deposition may be used to diagnose the cause of the arcing and suggest steps to minimize or prevent further occurrences. Techniques used to avoid arcing may include maintaining the pressure in the processing chamber about a de minimis level for the deposition process, setting the low-frequency RF power to less than 30% of the total RF power, and/or reducing the total RF power used for generating the plasma.

Additional techniques may also include adjusting the timing and/or flow rate at which one or more of the precursor materials used to generate the plasma is introduced to the processing chamber. For example, the timing of the introduction of a precursor gas into the processing chamber may be moved from being introduced after the RF power is supplied, to being introduced before the RF power is activated. Techniques may further include adjusting the ramp rate at which the RF power is activated. Conventional activation of the RF power has the power going from zero to peak power in as short a period of time as possible, with typically ramp rates for high-frequency RF power being about 5000 watts/sec or more, and ramp rates for low-frequency power being about 350 watts/second or more. Arcing may be reduced by lowering the ramp rates to, for example, about 600 watts/second or less for the high-frequency RF power, and 250 watts/second or less for the low-frequency RF power.

Example Substrate Processing Methods

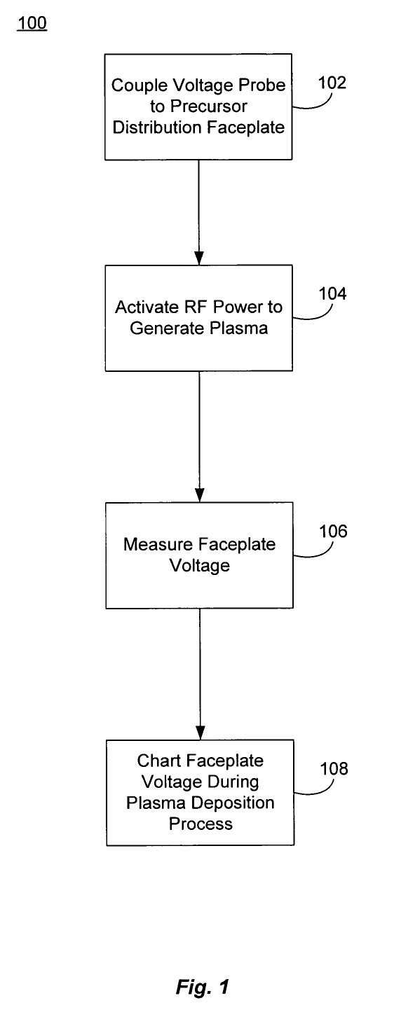

Referring now to FIG. 1, a method 100 of detecting arcing in a semiconductor wafer processing chamber is shown. The method 100 includes coupling a voltage probe to the precursor distribution faceplate 102 of the processing chamber. The precursor distribution faceplate may act as both a manifold for delivering precursor fluids (e.g., TEOS, SiH₄, He, Ar, N₂, N₂O, O₂, O₃, etc.) to the processing chamber, and an electrode coupled to an RF power source to deliver RF power to the chamber. During a plasma deposition operation, the DC bias voltage applied to the faceplate may range from about 200 volts to about 600 volts, and the voltage probe typically has 100:1 division ratio to provide a signal output of about 2 to 6 volts. The voltage probe may also be coupled to a voltage measurement device that samples the faceplate voltage.

With the voltage probe coupled to the faceplate, the RF power source may be activated 104 to supply RF power to the processing chamber for generating the plasma. The RF power source may include multiple units to generate RF power a different frequencies. For example, the RF power source may include a high-frequency (e.g., 10 MHz or more, 13.65 MHz) power generator that supplies HF RF power for ionizing the plasma precursor materials into a plasma, and a low-frequency (e.g., about 50 to about 500 kHz) power source that supplies LF RF power for directing the ionized plasma to the surface of the substrate wafer. The voltage probe may be coupled to the faceplate such that the probe does not come into direct contact with the plasma generated in the processing chamber.

The faceplate voltage may be measured 106 over the course of the plasma deposition using the voltage measurement device. The device may be a fast acquisition device that can sample the faceplate voltage at a rate of 100,000 time per second (i.e., 100 kHz) or more. The voltage measurement device may also have the capability to chart the faceplate voltage as a function of time during the plasma deposition process 108. The plot may include signature features that indicate arcing has occurred in the processing chamber, and may be used as a aid for the diagnosing and correction of excessive arcing during the plasma deposition process.

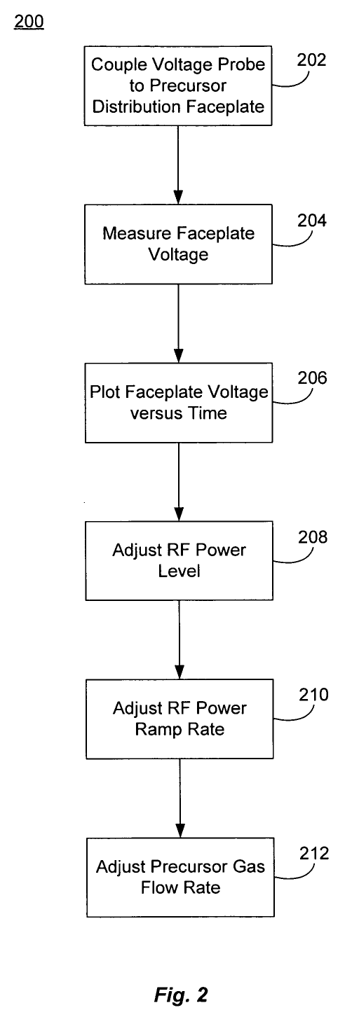

FIG. 2 shows a flowchart illustrating a method 200 of reducing arcing in a semiconductor wafer processing chamber according to embodiments of the invention. The method 200 may start with the coupling of a voltage probe to the precursor distribution faceplate 202 of the processing chamber (e.g., a PECVD processing chamber, HDPCVD processing chamber, etc.), and the measurement of the faceplate voltage 204. A high-speed voltage measurement device may be coupled to the voltage probe to generate a plot of the faceplate voltage measurements over time 206. The plot may include features (e.g., voltage spikes) that indicate arcing in the processing chamber, and these features may be used to diagnose and correct the underlying causes of the arcing.

In method 200, three adjustment are made to the plasma deposition process to reduce (or eliminate) arcing during the plasma deposition. These adjustments may include changing the RF power level 208, such as reducing the overall RF power supplied to the processing chamber. When multiple frequencies of RF power are supplied to the processing chamber, the power adjustment may be made to one or more RF frequencies (e.g., adjusting either the LF RF power level or the HF RF power level in a two-frequency RF source). Power level adjustments may also include decreasing or stopping the RF power before the end of the deposition to avoid arcing caused by voltage buildup in the process chamber.

Adjustments may also be made to the ramp rate at which the RF power is supplied to the processing chamber 210. In conventional PECVD deposition processes, the HF RF power is commonly ramped to the peak power level as fast as possible (e.g., 5000 watts/sec or faster). Adjustment to the ramp rate may include lowering the ramp rate for the HF RF power and/or the LF RF power, and may also include ramping the power in steps instead of one continuous increase from zero watts to the peak power level. For example, if the peak HF RF power level is 1600 watts, the ramp rate may include a first ramp-up step that increases the power from 0 to 1250 watts and a second ramp-up step that increases the power from 1250 watts to peak power at 1600 watts.

Adjustments may further be made to the flow rates of one or more of the precursor gases 212 used to form the plasma. For example, in a plasma deposition of a fluorine-doped silicate glass (FSG) film, the flow rate of the silicon or fluorine precursor gas may be reduced to avoid arcing. The adjustments may also include a change in the timing of the introduction of one or more precursors to the processing chamber. For example, the introduction of a fluorine precursor may be changed to start before the RF power is activated to reduce arcing during the initial formation of the plasma in the processing chamber.

It should be appreciated that not all the adjustment 208, 210, and 212 have to be made to reduce arcing during a PECVD deposition. Any combination of one or more of the adjustment may be adequate to reduce or eliminate arcing, depending on the characteristics of the deposition process. Furthermore, the present invention contemplates that other adjustments may be made in addition to (or in lieu of) the adjustments 208, 210, and 212 described above (e.g., maintaining the pressure in the processing chamber about a de minimis level for the deposition process, setting the low-frequency RF power to less than 30% of the total RF power, reducing the total RF power used for generating the plasma, etc.).

Example Substrate Processing System

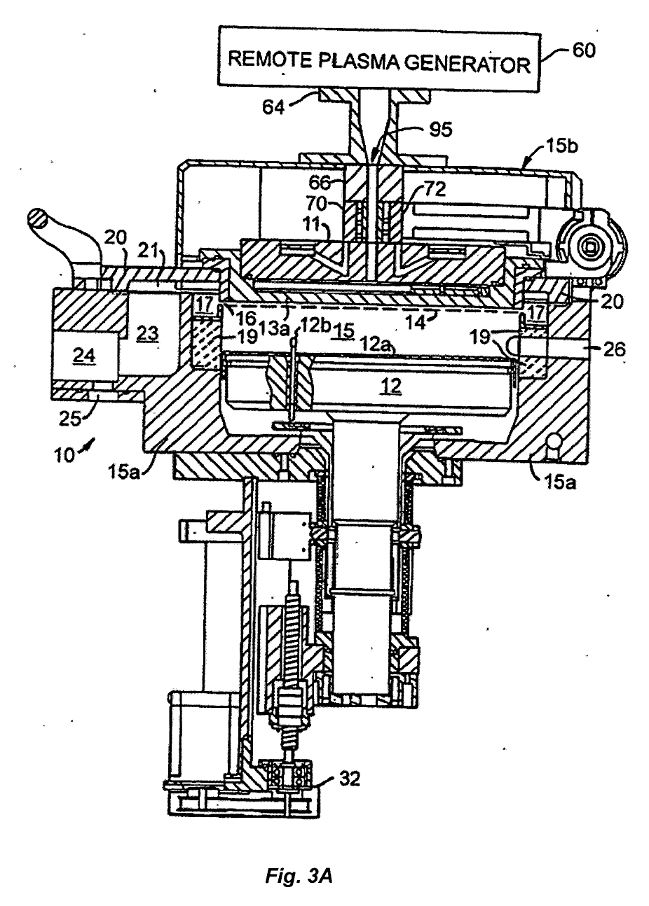

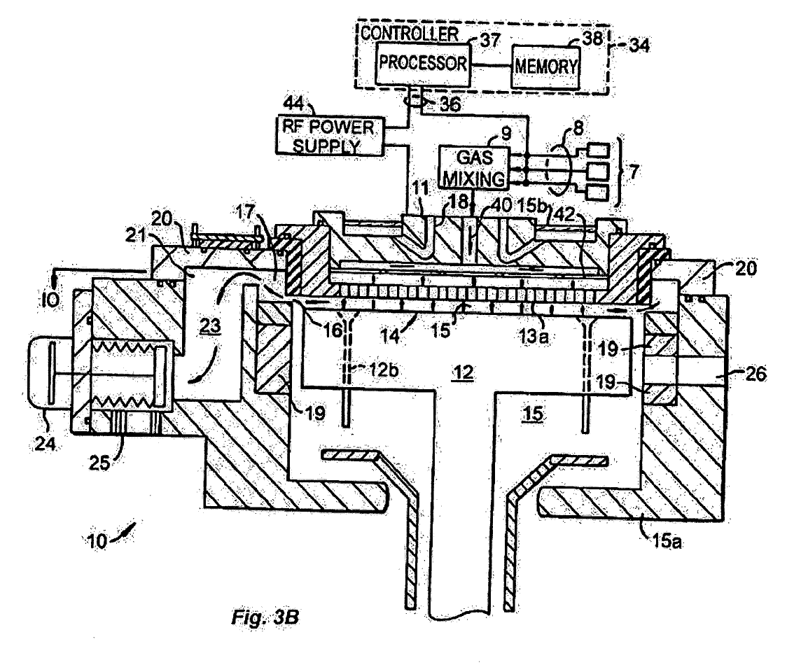

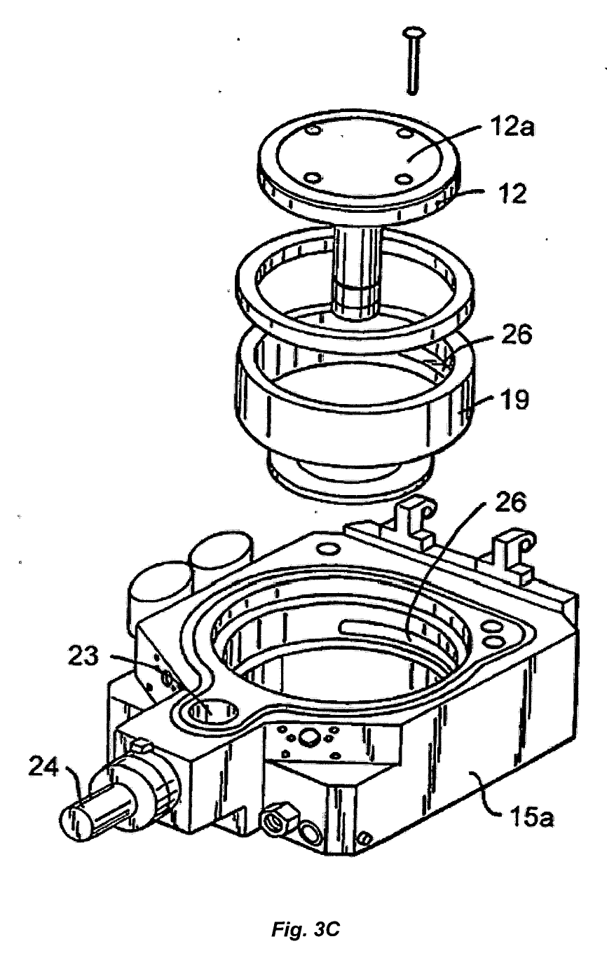

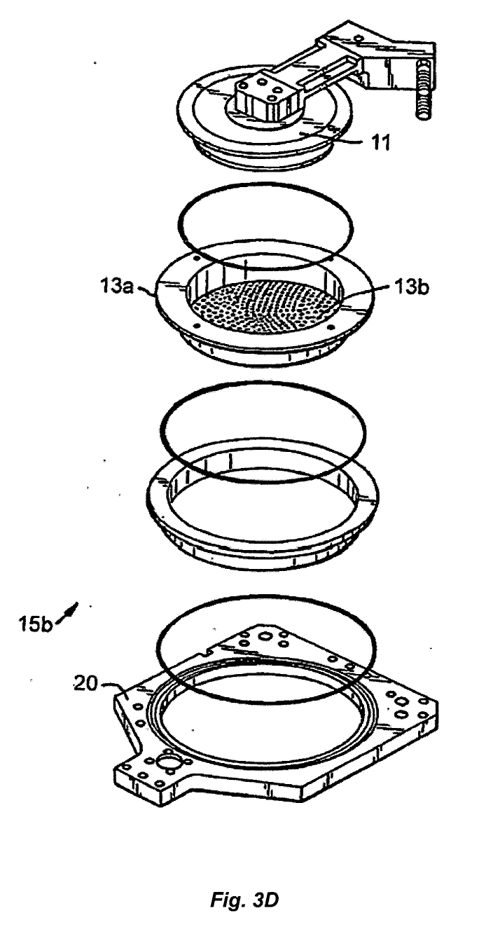

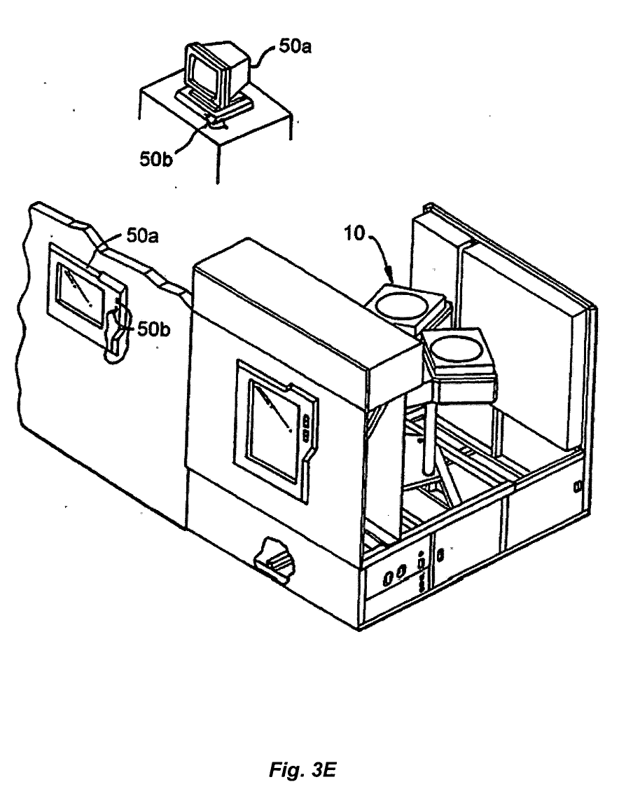

One suitable substrate processing system in which the method of the present invention can be carried out is shown in FIGS. 3A and 3B, which are vertical, cross-sectional views of a CVD system 10, having a vacuum or processing chamber 15 that includes a chamber wall 15a and a chamber lid assembly 15b. The chamber wall 15a and chamber lid assembly 15b are shown in exploded, perspective views in FIGS. 3C and 3D.

The CVD system 10 contains a gas distribution fold 11 for dispersing process gases to a substrate (not shown) that rests on a heated pedestal 12 centered within the process chamber 15. During processing, the substrate (e.g., a semiconductor wafer) is positioned on a flat (or slightly convex) surface 12a of the pedestal 12. The pedestal 12 can be moved controllably between a lower loading/off-loading position (depicted in FIG. 3A) and an upper processing position (indicated by dashed line 14 in FIG. 3A and shown in FIG. 3B), which is closely adjacent to the manifold 11. A centerboard (not shown) includes sensors for providing information on the position of the wafers.

Deposition and carrier gases are introduced into the chamber 15 through perforated holes 13b (FIG. 3D) of a conventional flat, circular gas distribution faceplate 13a. More specifically, deposition process gases flow into the chamber through the inlet manifold 11 (indicated by arrow 40 in FIG. 3B), through a conventional perforated blocker plate 42 and then through holes 13b in gas distribution faceplate 13a.

Before reaching the manifold 11, deposition and carrier gases are input from gas sources 7 through gas supply lines 8 (FIG. 3B) into a mixing system 9 where they are combined and then sent to manifold 11. Generally, the supply line for each process gas includes (i) several safety shut-off valves (not shown) that can be used to automatically or manually shut-off the flow of process gas into the chamber, and (ii) mass flow controllers (also not shown) that measure the flow of gas through the supply line. When toxic gases are used in the process, the several safety shut-off valves are positioned on each gas supply line in conventional configurations.

The deposition process performed in the CVD system 10 can be either a thermal process or a plasma-enhanced process. In a plasma-enhanced process, an RF power supply 44 applies electrical power between the gas distribution faceplate 13a and the pedestal 12 so as to excite the process gas mixture to form a plasma within the cylindrical region between the faceplate 13a and the pedestal 12. (This region will be referred to herein as the “reaction region”). Constituents of the plasma react to deposit a desired film on the surface of the semiconductor wafer supported on pedestal 12. RF power supply 44 is a mixed frequency RF power supply that typically supplies power at a high frequency (RF1) of 13.56 MHz and at a low RF frequency (RF2) of 360 KHz to enhance the decomposition of reactive species introduced into the vacuum chamber 15. In a thermal process, the RF power supply 44 would not be utilized, and the process gas mixture thermally reacts to deposit the desired films on the surface of the semiconductor wafer supported on the pedestal 12, which is resistively heated to provide thermal energy for the reaction.

In the embodiment of the system shown in FIG. 3A, a remote plasma generator 60 is mounted on the lid assembly 15b of the process chamber 15, including the gas distribution faceplate 13a and the gas distribution manifold 11. A mounting adaptor 64 mounts the plasma generator 60 on the lid assembly 15b. The adaptor 64 may be made of metal, and may include a conduit 95 for process gases traveling between the generator 60 and chamber 15. A mixing device 70 may be coupled to the upstream side of the gas distribution manifold 11. The mixing device 70 may include a mixing insert 72 disposed inside a slot 74 of a mixing block 76 for mixing process gases. A ceramic isolator 66 may be placed between the mounting adaptor 64 and the mixing device 70. The ceramic isolator 66 may be made of a ceramic material, such as alumina, or a polymer such as Teflon™, among other materials. When installed, the mixing device 70 and ceramic isolator 66 form part of the lid assembly 15b. The isolator 66 isolates the adaptor 64 from the mixing device 70 and gas distribution manifold 11 to reduce the potential for a secondary plasma to form in the lid assembly 15b.

During a plasma-enhanced deposition process, the plasma heats the entire process chamber 10, including the walls of the chamber body 15a surrounding the exhaust passageway 23 and the shut-off valve 24. When the plasma is not turned on or during a thermal deposition process, a hot liquid is circulated through the walls 15a of the process chamber 15 to maintain the chamber at an elevated temperature. A portion of these heat exchanging passages 18 in the lid assembly 15b of chamber 15 is shown FIG. 3B. The passages in the remainder of the chamber walls 15a are not shown. Fluids used to heat the chamber walls 15a include the typical fluid types, i.e., water-based ethylene glycol or oil-based thermal transfer fluids. This heating (referred to as heating by the “heat exchanger”) beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The remainder of the gas mixture that is not deposited in a layer, including reaction byproducts, is evacuated from the chamber 15 by a vacuum pump (not shown). Specifically, the gases are exhausted through an annular, slot-shaped orifice 16 surrounding the reaction region and into an annular exhaust plenum 17. The annular slot 16 and the plenum 17 are defined by the gap between the top of the chamber's cylindrical side wall 15a (including the upper dielectric lining 19 on the wall) and the bottom of the circular chamber lid 20. The 360° circular symmetry and uniformity of the slot orifice 16 and the plenum 17 are important to achieving a uniform flow of process gases over the wafer so as to deposit a uniform film on the wafer.

From the exhaust plenum 17, the gases flow underneath a lateral extension portion 21 of the exhaust plenum 17, past a viewing port (not shown), through a downward-extending gas passage 23, past a vacuum shut-off valve 24 (whose body is integrated with the lower chamber wall 15a), and into the exhaust outlet 25 that connects to the external vacuum pump (not shown) through a foreline (also not shown).

The wafer support platter of the pedestal 12 (preferably aluminum, ceramic, or a combination thereof) is resistively heated using an embedded single-loop embedded heater element configured to make two full turns in the form of parallel concentric circles. An outer portion of the heater element runs adjacent to a perimeter of the support platter, while an inner portion runs on the path of a concentric circle having a smaller radius. The wiring to the heater element passes through the stem of the pedestal 12.

Typically, any or all of the chamber lining, gas inlet manifold faceplate, and various other reactor hardware are made out of material such as aluminum, anodized aluminum, or ceramic. An example of such a CVD apparatus is described in U.S. Pat. No. 5,558,717 entitled “CVD Processing Chamber,” issued to Zhao et at. The U.S. Pat. No. 5,558,717 patent is assigned to Applied Materials, Inc., the assignee of the present invention, and is hereby incorporated by reference in its entirety for all purposes.

A lift mechanism and motor 32 (FIG. 3A) raises and lowers the heater pedestal assembly 12 and its wafer lift pins 12b as wafers are transferred into and out of the body of the chamber 15 by a robot blade (not shown) through an insertion/removal opening 26 in the side of the chamber 10. The motor 32 raises and lowers pedestal 12 between a processing position 14 and a lower, wafer-loading position. The motor, valves or flow controllers connected to the supply lines 8, gas delivery system, throttle valve, RF power supply 44, and chamber and substrate heating systems are all controlled by a system controller 34 (FIG. 3B) over control lines 36, of which only some are shown. Controller 34 relies on feedback from optical sensors to determine the position of movable mechanical assemblies such as the throttle valve and susceptor which are moved by appropriate motors under the control of controller 34.

In the exemplary embodiment shown in FIG. 3B, the system controller includes a hard disk drive (memory 38), a floppy disk drive and a processor 37. The processor contains a single-board computer (SBC), analog and digital input/output boards, interface boards and stepper motor controller boards. Various parts of CVD system 10 conform to the Versa Modular European (VME) standard which defines board, card cage, and connector dimensions and types. The VME standard also defines the bus structure as having a 16-bit data bus and a 24-bit address bus.

System controller 34 controls all of the activities of the CVD machine. The system controller executes system control software, which is a computer program stored in a computer-readable medium such as a memory 38. Preferably, the memory 38 is a hard disk drive, but the memory 38 may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to operate controller 34.

A process for depositing a film on a substrate or a process for cleaning the chamber 15 can be implemented using a computer program product that is executed by the controller 34. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Windows™ library routines. To execute the linked, compiled object code the system user invokes the object code, causing the computer system to load the code in memory. The CPU then reads and executes the code to perform the tasks identified in the program.

The interface between a user and the controller 34 is via a CAT monitor 50a and light pen 50b, shown in FIG. 3E, which is a simplified diagram of the system monitor and CVD system 10 in a substrate processing system, which may include one or more chambers. In the preferred embodiment two monitors 50a are used, one mounted in the clean room wall for the operators and the other behind the wall for the service technicians. The monitors 50a simultaneously display the same information, but only one light pen 50b is enabled. A light sensor in the tip of light pen 50b detects light emitted by CRT display. To select a particular screen or function, the operator touches a designated area of the display screen and pushes the button on the pen 50b. The touched area changes its highlighted color, or a new menu or screen is displayed, confirming communication between the light pen and the display screen. Other devices, such as a keyboard mouse, or other pointing or communication device, may be used instead of or in addition to light pen 50b to allow the user to communicate with controller 34.

### EXAMPLES

### Example 1

Arcing During Deposition of FSG Film

In these examples, fluorine-doped-silicate (FSG) layers (generally having a 8 μm thickness) were deposited on a 300 mm silicon-on-insulator (SOI) substrate wafers in PECVD processes. The PECVD processing chamber used for the depositions was a Producer™ SE chamber made by Applied Materials, Inc. of Santa Clara, Calif. Plasma was generated and deposited on the substrate wafers using a dual-frequency RF power source that supplied high-frequency (i.e., 13.56 MHz) RF power and low-frequency (i.e., 350 kHz) RF power to the processing chamber. Table 1 shows additional processing details for various phases of a standard deposition run in the chamber:

TABLE 1
Baseline FSG Layer Deposition Run with PECVD Producer Chamber

| Process | TOES | Initiation | Deposition | Termination | Exhaust |
|---|---|---|---|---|---|
| Condition | On | Phase | Phase | Phase | Phase |
| Max Time | 10 | 1-2 | 82 | 2 | 10 |
| (sec) | | | | | |
| Temp (° C.) | 400 | 400 | 400 | 400 | 400 |
| Pressure (Torr) | 6 | 6 | 6 | 6 | 0 |
| Heater Space | 285 | 285 | 285 | 285 | 285 |
| (mils) | | | | | |
| RF Time (sec) | 0 | 1 | 82 | 2 | 0 |
| HF RF Power | 0 | 1250 | 1600 | 1600 | 0 |
| (Watts) | | | | | |
| HF RF Ramp | 0 | 5000 | 5000 | 5000 | 0 |
| Rate (W/sec) | | | | | |
| LF RF Power | 0 | 0 | 700 | 0 | 0 |
| (Watts) | | | | | |
| LF RF Ramp | 0 | 0 | 350 | 0 | 0 |
| Rate (W/sec) | | | | | |
| RF Match | M4 | M4 | M4 | M4 | M4 |
| TEOS (mgm) | 4600 | 4600 | 4600 | 4600 | 0 |
| SiF₄ (sccm) | 0 | 0 | 1025 | 1025 | 0 |
| He Carrier | 6000 | 6000 | 6000 | 6000 | 0 |
| (sccm) | | | | | |
| N₂O (sccm) | 1600 | 1600 | 1600 | 1600 | 0 |
| O₂ (sccm) | 2700 | 2700 | 2700 | 2700 | 0 |

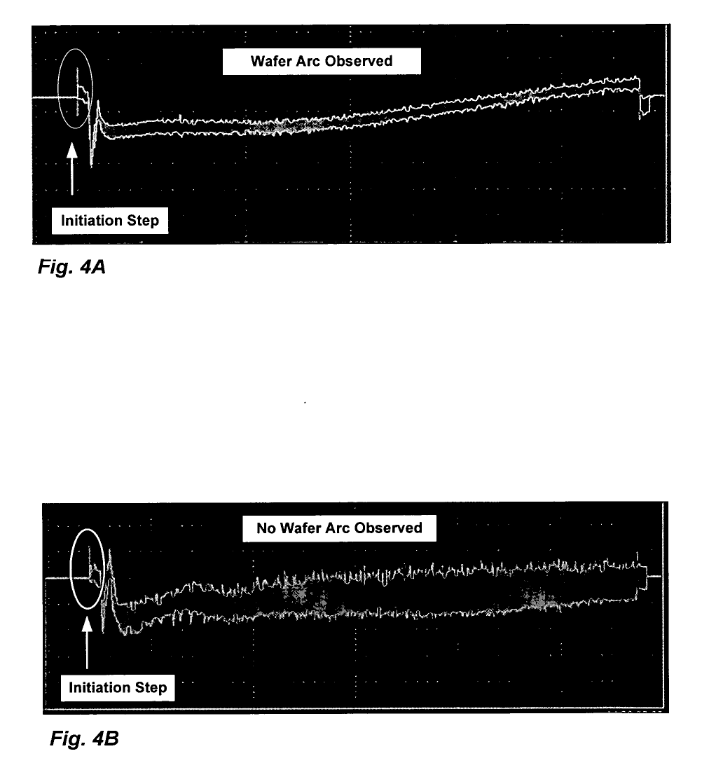

A voltage probe was connected to the plasma precursor distribution faceplate to monitor changes in the DC bias voltage of the faceplate over time. The DC bias on the faceplate typically ranges from 200-600 Volts, and 100:1× probe was used to reduce the range of the probe output signal from 1-10 Volts. The probe was connected to a signal acquisition device that sampled the faceplate voltage at a rate of 100 kHz, and a plot was made of the faceplate voltage as a function of time over the course of the deposition. FIG. 4A is the plot for the baseline deposition run, which shows a voltage spike at during the initiation step which indicates an arcing event took place as the RF power source was being ramped up to full power.

The plot in FIG. 4A shows a correlation between the arcing and the activation of the RF power supply, and was used to diagnose a problem with the ramp rate of the RF power supplied to generate and deposit the plasma on the substrate wafer. To test the diagnosis, another FSG deposition run was performed where the high-frequency RF power ramp rate was reduced from 5000 watts/sec to 600 watts/sec, and the low-frequency RF power ramp rate was reduced from 350 watts/sec to 250 watts/sec. In addition, the peak low-frequency RF power was reduced from 700 watts to 500 watts. Table 2 shows additional processing details for the various phases of the new deposition run in the processing chamber:

TABLE 2
New FSG Layer Deposition Run with PECVD Producer Chamber

| Process | | Initiation | Initiation | Deposition | Termination | Exhaust |
|---|---|---|---|---|---|---|
| Condition | TOES On | Phase 1 | Phase 2 | Phase | Phase | Phase |
| Max Time | 15 | 2 | 1 | 82 | 2 | 10 |
| (sec) | | | | | | |
| Temp (° C.) | 400 | 400 | 400 | 400 | 400 | 400 |
| Pressure | 6 | 6 | 6 | 6 | 6 | 0 |
| (Torr) | | | | | | |
| Heater Space | 285 | 285 | 285 | 285 | 285 | 285 |
| (mils) | | | | | | |
| RF Time (sec) | 0 | 1 | 1 | 82 | 2 | 0 |
| HF RF Power | 0 | 1250 | 1250 | 1600 | 1600 | 0 |
| (Watts) | | | | | | |
| HF RF Ramp | 0 | 600 | 600 | 600 | 600 | 0 |
| Rate (W/sec) | | | | | | |
| LF RF Power | 0 | 0 | 0 | 500 | 0 | 0 |
| (Watts) | | | | | | |
| LF RF Ramp | 0 | 0 | 0 | 250 | 0 | 0 |
| Rate (W/sec) | | | | | | |
| RF Match | M4 | M4 | M4 | M4 | M4 | M4 |
| TEOS (mgm) | 4600 | 4600 | 4600 | 4600 | 4600 | 0 |
| SiF₄ (sccm) | 0 | 0 | 0 | 1025 | 1025 | 0 |
| He Carrier | 6000 | 6000 | 6000 | 6000 | 6000 | 0 |
| (sccm) | | | | | | |
| N₂O (sccm) | 1600 | 1600 | 1600 | 1600 | 1600 | 0 |
| O₂ (sccm) | 2700 | 2700 | 2700 | 2700 | 2700 | 0 |

The plot in FIG. 4B shows the voltage spike had disappeared when the lower ramp rates and lower peak low-frequency RF power was used during the PECVD deposition, confirming the diagnosis that RF power higher ramp rates, and peak LF RF power was causing arcing in the processing chamber.

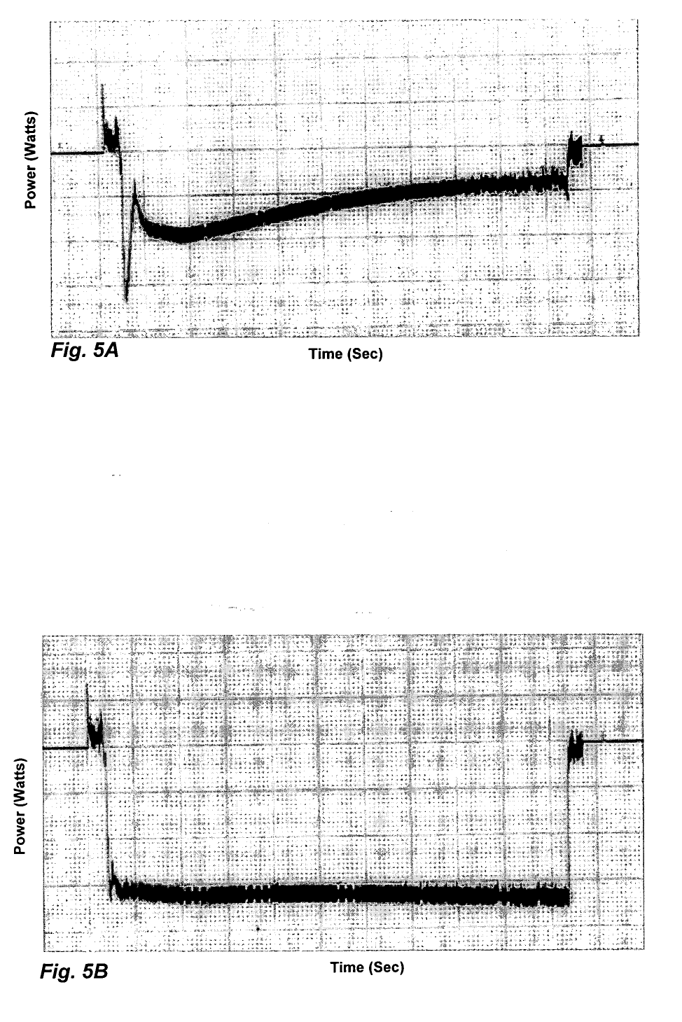

An additional test was conducted to determine if both the ramp rate and the peak power level for the low-frequency RF should be reduced to prevent arcing during the activation of the RF power source. In this experimental run, the LF RF ramp rate was kept at the higher 350 watts/second rate, while the LF RF peak power was reduced to 350 watts. FIGS. 5A-B show plots of the DC bias voltage on the faceplate as a function of time for LF RF peak powers of 700 watts (FIG. 5A) and 350 watts (FIG. 5B). Consistent with the baseline processing run, the plot in FIG. 5A shows a significant voltage spike at the start of the run, indicating arcing had occurred during the activation of the RF power source. In contrast, FIG. 5B shows that arcing is prevented at the same LF RF power ramp rate, when the LF RF peak power level is cut in half.

FIGS. 5A-B demonstrate that arcing can be prevented during the activation of the RF power source by reducing the LF RF ramp rate and/or the peak LF RF power. The adjustments made to either (or both) processing parameters may vary depending on the run being conducted. Lowering the high and low-frequency RF ramp rates too much can create instabilities in the plasma formed, as well as changing the chemistry of the layer being deposited on the substrate wafer. Lowering the peak LF RF power too much can slow the rate of plasma deposition on the substrate wafer, and reduce the overall efficiency of the fabrication process. Additional experimentation may be conducted to find RF ramp rates and power levels that do not cause arcing at the start of the process and also provide a high level of quality and efficiency for the deposited layer.

### Example 2

Arcing During Deposition of Integrated USG-FGS Film

In this example, an integrated undoped silicate glass (USG) and fluorine-doped-silicate (FSG) film was deposited on a 300 mm silicon-on-insulator (SOI) substrate wafer in a PECVD process. The PECVD processing chamber used for the deposition was a Producer™ SE chamber made by Applied Materials, Inc. of Santa Clara, Calif. Plasma was generated and deposited on the substrate wafer using a dual-frequency RF power source that supplied high-frequency (i.e., 13.56 MHz) RF power and low-frequency (i.e., 350 kHz) RF power to the processing chamber. The deposition started with the depositing of the USG material on the substrate wafer, followed by a transition to the deposition of the FSG material.

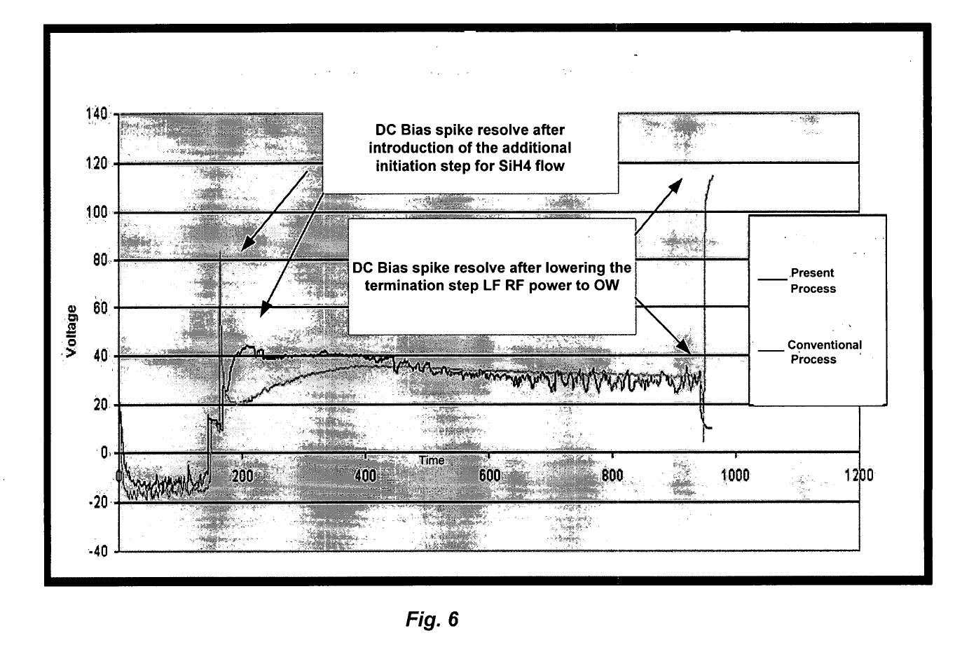

In a baseline process example, the transition from USG to FSG depositions was discontinuous with the USG process gases and RF power being terminated before the FSG process gases and RF power is initiated. FIG. 6 shows a plot of the DC bias voltage on the faceplate of the processing chamber during the baseline process, with voltage spikes appearing at both the initiation and termination of the FSG deposition phase. The plot was used to diagnose arcing problems at both ends of FSG deposition.

The diagnosis based on the plot in FIG. 6 was that the initial arcing was caused by instability in the plasma created by the near simultaneous introduction of the process gases and RF power in the processing chamber. This arcing may be mitigated by introducing one or more of the process gases prior to activating the RF power. The arcing at the termination of the FSG deposition was believed to be caused by the voltage build-up at the electrodes, which was discharged as the processes gases and RF power were nearly simultaneously shut down. This arcing may be mitigated by powering down the LF RF power before the deposition step is completely terminated.

A new experimental run was conducted with a modified FSG deposition phase based on the diagnosis above. In the modified FSG deposition, SiF₄ was introduced to the chamber before the RF power was activated, and the low-frequency RF power was shut off at the start of the termination phase to minimize the DC bias spike during termination of the FSG deposition. The second plot in FIG. 6 shows that modifications made to the FSG deposition eliminated the voltage spikes observed at the beginning and end of the deposition.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the electrode” includes reference to one or more electrodes and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of diagnosing an arcing problem in a semiconductor wafer processing chamber, the method comprising:
coupling a voltage probe to a process-gas distribution faceplate in the processing chamber;
activating an RF power source to generate a plasma between the faceplate and a substrate wafer; and
measuring the DC bias voltage of the faceplate as a function of time during the activation of the RF power source, wherein a spike in the measured voltage at the faceplate indicates an arcing event has occurred in the processing chamber.

2. The method of claim 1, wherein the semiconductor wafer processing chamber is a plasma-enhanced chemical vapor deposition chamber.

3. The method of claim 1, wherein the DC bias voltage of the faceplate is measured at a sampling rate of about 100 kHz or more.

4. The method of claim 1, further comprising adjusting a power ramp rate for the RF power source in response to the arcing event.

5. The method of claim 4, wherein the power ramp rate for the RF power source comprises a low-frequency ramp rate to provide low-frequency RF power in the processing chamber, and a high-frequency ramp rate to provide high-frequency RF power in the processing chamber.

6. The method of claim 5, wherein the low-frequency ramp rate is about 250 watts/second or less.

7. The method of claim 5, wherein the high-frequency ramp rate is about 600 watts/second or less.

8. The method of claim 1, further comprising adjusting a RF power level of the RF power source in response to the arcing event.

9. The method of claim 8, wherein the adjustment of the RF power level comprises reducing a low-frequency RF power level by about 25% or more.

10. The method of claim 1, further comprising adjusting a flow rate for a plasma precursor in response to the arcing event.

11. The method of claim 10, wherein the plasma precursor comprises tetraethylorthosilicate (TEOS).

12. The method of claim 10, wherein the plasma precursor comprises SiF₄.

13. The method of claim 1, wherein the voltage probe does not contact the plasma.

14. A system to diagnose an arcing problem in a semiconductor wafer processing chamber, the system comprising:
a voltage probe coupled to a process-gas distribution faceplate in the processing chamber; and
a voltage measurement device to measure the DC bias voltage of the faceplate as a function of time; and
a display coupled to the voltage measurement device to display a plot of faceplate voltage measurements as a plasma is generated in the processing chamber, wherein a spike in the plot indicates an arcing event has occurred in the processing chamber.

15. The system of claim 14, wherein the voltage measurement device measures the DC bias voltage of the faceplate at a sampling rate of about 100 kHz or more.

16. The system of claim 14, wherein the voltage probe does not contact the plasma.

17. The system of claim 14, wherein the semiconductor wafer processing chamber is a plasma-enhanced chemical vapor deposition chamber.

18. A method to reduce arcing in a semiconductor wafer processing chamber, the method comprising:
measuring a spike in a DC bias voltage of a process-gas distribution faceplate as a plasma is formed in the processing chamber, wherein the spike indicates there is arcing in the chamber;
adjusting a flow rate of a plasma precursor material supplied to the chamber; and
adjusting a ramp rate for RF power supplied to the chamber to form the plasma from the plasma precursor material.

19. The method of claim 18, wherein the method further comprises reducing an RF power level supplied to the chamber to form the plasma.

20. The method of claim 18, wherein the adjustment of the ramp rate for the RF power comprises decreasing a low-frequency RF power ramp rate to about 250 watts/second or less, and decreasing a high-frequency RF power ramp rate to about 600 watts/second or less.
